(19) United States
(12) Patent Application Publication
(10) Pub. No.: US 2026/0334166 A1
(43) Pub. Date: Oct. 22, 2026

(54) APPARATUS AND METHOD OF MANUFACTURING SAMPLE AND METHOD OF MANUFACTURING SEMICONDUCTOR DEVICE BY USING THE APPARATUS AND METHOD

(71) Applicant: SAMSUNG ELECTRONICS CO., LTD., Suwon-si (KR)

(72) Inventors: Minchul JO, Suwon-si (KR); Kyusang Cho, Suwon-si (KR); Sanghyun Park, Suwon-si (KR); Gilho Gu, Suwon-si (KR)

(73) Assignee: SAMSUNG ELECTRONICS CO., LTD., Suwon-si (KR)

(21) Appl. No.: 19/468,474

(22) Filed: Feb. 3, 2026

(30) Foreign Application Priority Data
Apr. 3, 2025 (KR) 10-2025-0043735
Jul. 10, 2025 (KR) 10-2025-0093321

(51) Int. Cl. H10P 74/20; B23K 26/03; B23K 26/042; B23K 26/364; H10P 54/20; H10P 54/92; H10P 54/94; B23K 101/40

(52) U.S. Cl. CPC H10P 74/203; B23K 26/032; B23K 26/042; B23K 26/364; H10P 54/20; H10P 54/92; H10P 54/94; B23K 2101/40

(57) ABSTRACT

Provided is a method of manufacturing a sample, the method including preparing an uncut wafer, and manufacturing a sample by emitting a laser beam onto the uncut wafer, wherein the manufacturing of the sample includes forming a passivation layer on the wafer, removing at least a portion of each of the wafer and the passivation layer, and removing a residual passivation layer.

### CROSS-REFERENCE TO RELATED APPLICATION

This application claims priority to Korean Patent Application Nos. 10-2025-0043735, filed on Apr. 3, 2025, and 10-2025-0093321, filed on Jul. 10, 2025, in the Korean Intellectual Property Office, the disclosures of which are incorporated by reference herein in their entireties.

### BACKGROUND

Embodiments relate to an apparatus and method of manufacturing a sample and a method of manufacturing a semiconductor device by using the apparatus and method, and more particularly, to an apparatus and method of manufacturing a sample by using a laser device and a method of manufacturing a semiconductor device by using the apparatus and method.

As the electronics industry advances rapidly and the demands of users increases, electronic devices are being miniaturized further and becoming more multifunctional. As electronic devices are miniaturized and reduced in weight, semiconductor packages are being miniaturized and reduced in weight, and moreover, semiconductor packages need a degree of high integration. However, as a degree of integration of semiconductor devices increases, an internal pattern of each semiconductor device has been complicated, and thus, a precise test method for semiconductor devices is required.

### SUMMARY

One or more embodiments provide an apparatus and method of manufacturing a sample, which have enhanced reliability, and a method of manufacturing a semiconductor device by using the apparatus and method.

The object of the disclosure is not limited to the aforesaid, but other objects not described herein will be clearly understood by those of ordinary skill in the art from descriptions below.

According to an aspect of one or more embodiments, there is provided a method of manufacturing a sample, the method including preparing an uncut wafer, and manufacturing a sample by emitting a laser beam onto the uncut wafer, wherein the manufacturing of the sample includes forming a passivation layer on the wafer, removing at least a portion of each of the wafer and the passivation layer, and removing a residual passivation layer.

According to another aspect of one or more embodiments, there is provided a method of manufacturing a sample, the method including preparing an uncut wafer, and manufacturing a sample by emitting a laser beam onto the uncut wafer, wherein the manufacturing of the sample includes forming a passivation layer on the wafer, removing at least a portion of each of the wafer and the passivation layer, and removing a residual passivation layer, and wherein the manufacturing of the sample further comprises aligning the wafer and a laser beam.

According to still another aspect of one or more embodiments, there is provided a method of manufacturing a semiconductor device, the method including preparing a wafer, performing a semiconductor process on the wafer, manufacturing a sample, based on the wafer on which the semiconductor process has been performed, testing the manufactured sample, and performing a post semiconductor process, wherein the manufacturing of the sample includes forming a passivation layer on the wafer, removing at least a portion of each of the wafer and the passivation layer, and removing a residual passivation layer, and wherein the manufacturing of the sample is performed by emitting a laser beam onto an uncut wafer.

According to further still another aspect of one or more embodiments, there is provided a sample manufacturing apparatus including a light source unit including a light source configured to generate and emit a laser beam and a transfer unit configured to transfer the laser beam, emitted from the light source unit, to a wafer, wherein a sample is manufactured by emitting the laser beam onto an uncut wafer before being divided into individual chips.

The light source unit may further include a wavelength converter configured to convert a wavelength band of the laser beam generated and emitted by the light source.

The sample manufacturing apparatus may further include a scan unit configured to align the wafer and the laser beam.

The scan unit may be configured to photograph an align key of the wafer to align the wafer and the laser beam.

The transfer unit may be configured to de-layer a region of about 10 μm × about 10 μm to a region of about 3,000 μm × about 3,000 μm in a horizontal direction, in the wafer.

The transfer unit may be configured to emit a laser beam, having a spot size of a diameter of about 1 μm to about 20 μm, onto the wafer.

The light source unit may be configured to generate and emit a laser beam having a wavelength band of about 100 nm to about 1,100 nm.

The light source unit may be configured to generate and emit a laser beam having an inter-pulse time interval of about 50 kHz to about 1,000 kHz.

The light source unit may be configured to generate and emit a laser beam such that a penetration remain depth of the laser beam is disposed within a range from about 0.1 μm up to about 200 μm.

The transfer unit may further include a power meter configured to measure an output of the laser beam.

### BRIEF DESCRIPTION OF DRAWINGS

Embodiments will be more clearly understood from the following detailed description taken in conjunction with the accompanying drawings in which:

FIG. 1 is a flowchart illustrating a method of manufacturing a sample, according to one or more embodiments;

FIG. 2 is a plan view illustrating a wafer for manufacturing a sample, according to one or more embodiments;

FIG. 3 is a partial enlarged view of some semiconductor dies of FIG. 2;

FIG. 4 is a flowchart illustrating a method of performing a de-layering process, according to one or more embodiments;

FIG. 5 is a schematic diagram illustrating a sample manufacturing apparatus according to one or more embodiments;

FIG. 6 is a cross-sectional view illustrating a shape of a sample according to one or more embodiments;

FIG. 7 is a cross-sectional view illustrating a shape of a sample according to one or more embodiments;

FIG. 8 is a scanning electron microscope (SEM) image illustrating a sample manufactured by a method of manufacturing a sample, according to one or more embodiments; and

FIG. 9 is a flowchart illustrating a method of performing a semiconductor device, according to one or more embodiments.

### DETAILED DESCRIPTION

Hereinafter, embodiments will be described in detail with reference to the accompanying drawings. Like reference numerals refer to like elements in the drawings, and their repeated descriptions are omitted. In the drawings, the thickness or size of each layer is exaggerated for convenience of description and clarity, and thus, may slightly differ from a real shape and ratio.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c. Also, the term “and/or” includes any and all combinations of one or more of the associated listed items. For example, an expression, “a and/or b” should be understood as including only a, only b and both a and b.

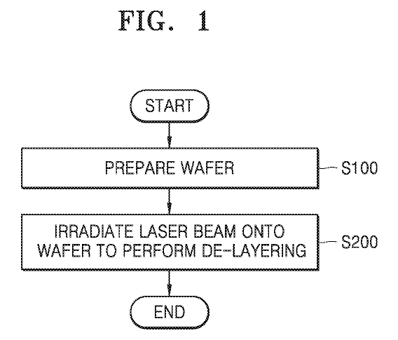

FIG. 1 is a flowchart illustrating a method of manufacturing a sample, according to one or more embodiments.

Referring to FIG. 1, the method of manufacturing a sample according to one or more embodiments may include a method which manufactures a sample for testing a result generated after a semiconductor process is performed. Here, the result may include a final result which is finished as all semiconductor processes are performed and/or an intermediate result which is finished as some semiconductor processes are performed. The method of manufacturing the sample according to one or more embodiments may include an operation of processing a wafer by using a laser, and this will be described below.

A wafer WT may be prepared in operation S100. The method of manufacturing the sample according to one or more embodiments may be performed by emitting a laser beam onto a wafer WT in a state of an uncut wafer (or a pre-dicing wafer) before being diced into individual chips.

A semiconductor manufacturing process may be performed by wafer units where a plurality of semiconductor chips are formed and may be maintained in a state, where a corresponding wafer is not cut, until before final packaging. A sampling, test, and/or measurement process according to one or more embodiments may be performed on a pattern which is formed on a wafer of an uncut state.

The wafer WT may include, for example, silicon (Si). The wafer WT may include a semiconductor element, such as germanium (Ge), or a compound semiconductor such as silicon carbide (SiC), gallium arsenide (GaAs), indium arsenide (InAs), or indium phosphide (InP).

In one or more embodiments, the wafer WT may have a silicon on insulator (SOI) structure. The wafer WT may include a buried oxide layer which is formed on a front-side surface of the wafer WT. According to one or more embodiments, the wafer WT may include a conductive region formed in the front-side surface of the wafer WT, and for example, may include an impurity-doped well. According to one or more embodiments, the wafer WT may have various device isolation structures such as shallow trench isolation (STI) which isolates the impurity-doped well.

A semiconductor device formed in the wafer WT may be one of a memory device and a non-memory device. According to one or more embodiments, the memory device may be a non-volatile NAND-type flash memory. According to one or more embodiments, the memory device may include phase change random access memory (RAM) (PRAM), magnetic RAM (MRAM), resistive RAM (ReRAM), ferroelectric RAM (FRAM), and NOR flash memory. Also, the memory device may be a volatile memory device where data is lost when power is cut off, like dynamic RAM (DRAM) and static RAM (SRAM). According to one or more embodiments, the memory device may be a logic chip, a measurement device, a digital signal processor (DSP), or a system-on-chip (SOC).

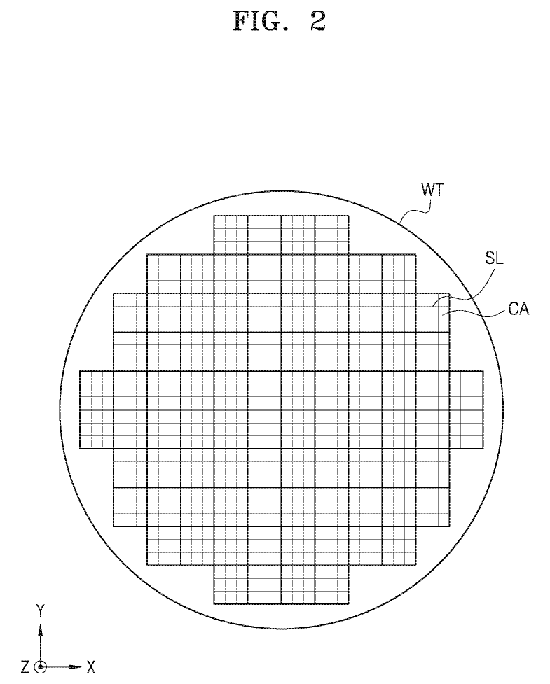

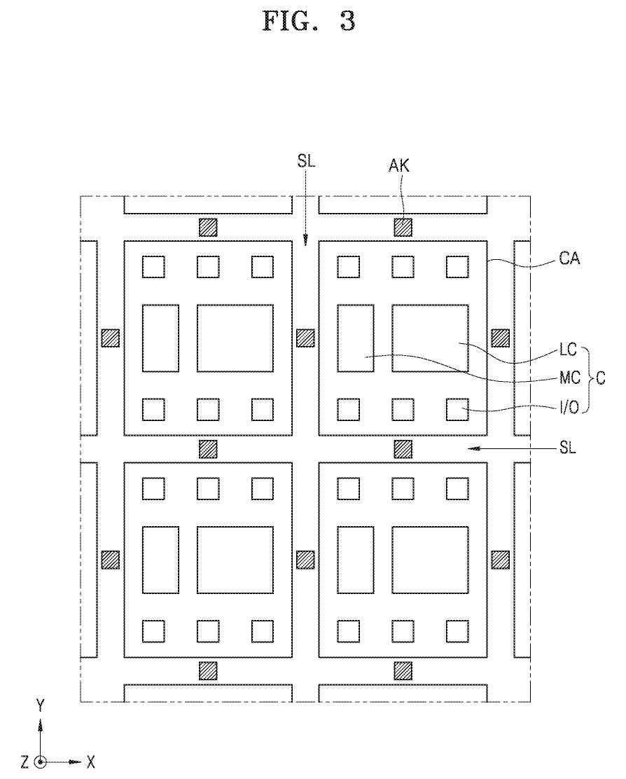

The wafer WT prepared in operation S100 will be described below with reference to FIGS. 2 and 3.

FIG. 2 is a plan view illustrating a wafer of manufacturing a sample, according to one or more embodiments. FIG. 3 is a partial enlarged view of one or more semiconductor dies of FIG. 2.

Referring to FIGS. 2 and 3, a wafer WT may include a plurality of chip regions CA. A scribe lane region SL may be disposed between the plurality of chip regions CA. The scribe lane region SL may be disposed between adjacent chip regions CA of the plurality of chip regions CA.

Each of the plurality of chip regions CA may include a plurality of circuit regions C. Each of the plurality of circuit regions CA may include a logic circuit region LC, a memory region M, and an input/output (I/O) element region I/O. In one or more embodiments, the method of manufacturing the sample according to one or more embodiments may be performed by removing a region corresponding to a scale of a chip region CA of the wafer WT, or may be performed by removing a region corresponding to a scale of each region configuring the circuit region C such as the logic circuit region LC.

A plurality of align keys AK may be disposed on the wafer WT. The plurality of align keys AK may each be a reference mark for the position alignment of test equipment and/or process alignment. For example, the align key AK may include a fiducial key. Although described below in detail, a position of the test equipment may be aligned based on the align key AK, and thus, a laser beam may be more precisely emitted onto the wafer WT.

In one or more embodiments, the plurality of align keys AK may be substantially and uniformly arranged on the wafer WT. In one or more embodiments, the plurality of align keys AK may be uniformly arranged in the scribe lane region SL. In one or more embodiments, the plurality of align keys AK may be uniformly arranged on the chip region CA. The plurality of align keys AK may be disposed on the wafer WT without covering the chip region CA and the scribe lane region SL.

The method of manufacturing the sample according to one or more embodiments may provide a method which more precisely distinguishes a laser emission region, based on an align key AK of an uncut wafer WT, and then, may emit a laser beam onto the laser emission region to manufacture a high-reliability sample.

Referring again to FIG. 1, after the wafer WT is prepared in operation S100, a de-layering process may be performed by emitting a laser beam onto the wafer WT in operation S200. Before describing operation S200, a de-layering process will be described.

The de-layering process may be a process of emitting a laser beam onto a plurality of layers (for example, a metal layer and/or a dielectric layer) formed in a semiconductor device and sequentially removing or detaching the layers, and thus, exposing a lower structure of the semiconductor device. The de-layering process may be performed through a focused ion beam (FIB), dry etching, wet etching, and/or a laser device. The presence of a defect, a material, and/or a shape of a per-layer structure of the semiconductor device may be determined by performing the de-layering process. Also, the de-layering process may more precisely control a removed thickness of each layer, and thus, may allow analysis limited to a certain vertical level (or a certain layer) and/or an interface to be easily performed.

A semiconductor process and/or a semiconductor device may be evaluated by performing electron microscope analysis, elemental analysis (EDS), and/or profile measurement on a portion exposed through the de-layering process.

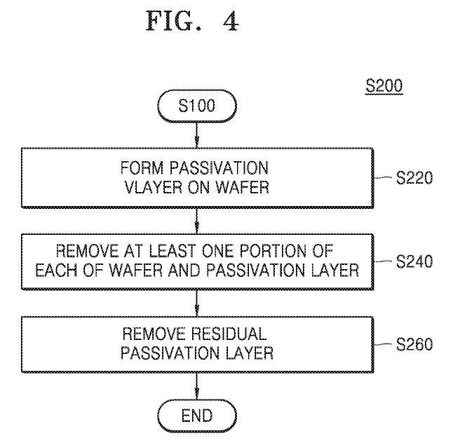

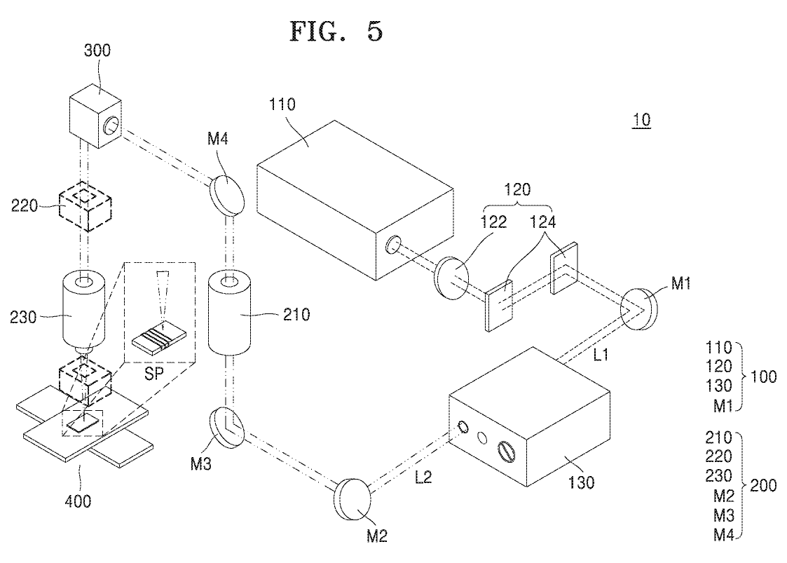

In the method of manufacturing the sample according to one or more embodiments, the de-layering process may be performed by emitting a laser beam. Operation S200 of performing the de-layering process will be described below with reference to FIGS. 4 and 5.

FIG. 4 is a flowchart illustrating a method of performing a de-layering process, according to one or more embodiments. FIG. 5 is a schematic diagram illustrating a sample manufacturing apparatus 10 according to one or more embodiments.

Before describing the de-layering process of FIG. 4, the sample manufacturing apparatus 10 of FIG. 5 may be first described. Referring to FIG. 5, the sample manufacturing apparatus 10 may include an operation of emitting a laser beam onto a wafer WT of an uncut state to perform a de-layering process on the wafer WT. The sample manufacturing apparatus 10 may include a light source unit 100, a transfer unit 200, a scan unit 300, and a stage 400.

The light source unit 100 may generate and emit light. The light source unit 100 may process the wafer WT to generate and emit light for forming a sample SP. For example, the light source unit 100 may be a system configured with a plurality of optical elements such as a collimator, a polarizer, and a condensing lens, but is not limited thereto.

The light source unit 100 may generate a light of a desired wavelength to input the light to the transfer unit 200. The light source unit 100 may generate and output light of a short wavelength and/or a multi-wavelength. For example, the light source unit 100 may generate and output coherent light. The coherent light may denote light which causes interference such as constructive interference or destructive interference due to a phase difference when two or more pieces of light overlap each other.

The light source unit 100 may include a light source 110, a light attenuator 120, a first mirror M1, and a wavelength converter 130. The light source 110 may generate and emit light. In one or more embodiments, the light source 110 may include a laser device which generates and outputs a laser beam. For example, the light source 110 may be one of a gas laser such as a helium-xenon laser, a xenon laser, and a carbon dioxide laser, a solid-state laser such as crystal laser and a yttrium aluminum garnet (YAG) laser, and a semiconductor layer such as a gallium arsenide (GaAs) laser and an indium phosphide (InP) laser. For example, the light source 110 may include a Nd:YAG laser oscillator, a Nd:YVO₄ laser oscillator, an AlGaInP laser, a GaN laser, a Nd fiber laser, and/or a sapphire-based laser oscillator.

The light source 110 may generate and emit visible light and/or light of an infrared ray wavelength. For example, the light source 110 may generate and emit visible light and/or light of a near infrared ray (NIR) wavelength. The light source 110 may generate and emit light having a wavelength of about 100 nm to about 1,100 nm. For example, the light source 110 may generate and emit light having a wavelength of about 100 nm to about 600 nm. The light source 110 may generate and output, for example, a femtosecond (fs) laser beam and/or a nanosecond (ns) laser beam. For example, the laser beam may have a pulse length of about 250 fs to about 500 ns. For example, the laser beam may have a pulse length of about 250 fs to about 50 ns. However, a pulse length of the laser beam is not limited thereto.

For example, the light source 110 may generate and output light having an output of about 0.5 W to about 50 W. For example, the light source 110 may generate and output light having an output of about 0.5 W to about 3 W. For example, the light source 110 may generate and emit light having nominal pulse energy of about 2.5 nJ to about 300 nJ. For example, the light source 110 may generate and emit light having nominal pulse energy of about 2.5 nJ to about 100 nJ.

For example, the light source 110 may generate and emit light having an inter-pulse time interval (or the number of pulses per second) of about 10 kHz to about 2,000 kHz. For example, the light source 110 may generate and emit light having an inter-pulse time interval (or the number of pulses per second) of about 50 kHz to about 1,000 kHz.

For example, the light source 110 may generate and emit light such that a penetration remain depth is about 0.1 μm to about 200 μm. For example, the light source 110 may generate and emit light such that the penetration remain depth is about 80 μm to about 120 μm.

The light attenuator 120 may adjust an output level of an optical signal. In one or more embodiments, the light attenuator 120 may decrease an output level of light generated by the light source 110. In one or more embodiments, the light attenuator 120 may increase the output level of the light generated by the light source 110. The light attenuator 120 may include a phase plate 122 and a polarization plate 124. The phase plate 122 and the polarization plate 124 may control a phase of an optical signal.

In FIG. 5, the light attenuator 120 is illustrated as including the phase plate 122 and the polarization plate 124, but is not limited thereto and the light attenuator 120 may further include an optical filter and may be configured based on a variable optical attenuator (VOA) and/or a Mach-Zehnder interferometer (MZI).

The first mirror M1 may control a path of a first laser beam LB1 such that a first laser beam LB1 passing through the light attenuator 120 is incident on the wavelength converter 130.

The wavelength converter 130 may convert a wavelength band of the first laser beam LB1. The wavelength converter 130 may convert the wavelength band of the first laser beam LB1 to convert the first laser beam LB1 into a second laser beam LB2. The wavelength converter 130 may convert the wavelength band of the first laser beam LB1 to convert the first laser beam LB1 into the second laser beam LB2 having a wavelength band suitable for manufacturing a sample. In one or more embodiments, the wavelength converter 130 may convert the first laser beam LB1 into light of a deep ultraviolet (UV) wavelength to generate the second laser beam LB2. For example, the wavelength converter 130 may convert the first laser beam LB1 into light having a wavelength of about 180 nm to about 250 nm to generate the second laser beam LB2.

When a semiconductor device includes a complex material, in a case where a de-layering process is performed by emitting light of an UV wavelength band onto the wafer WT, a per-material selectivity of the semiconductor device may be relatively large in deviation, and a non-uniformity and/or surface roughness of a surface of the sample SP after the wafer WT is processed may be relatively high. Therefore, the reliability of a process of testing the sample SP may be relatively low.

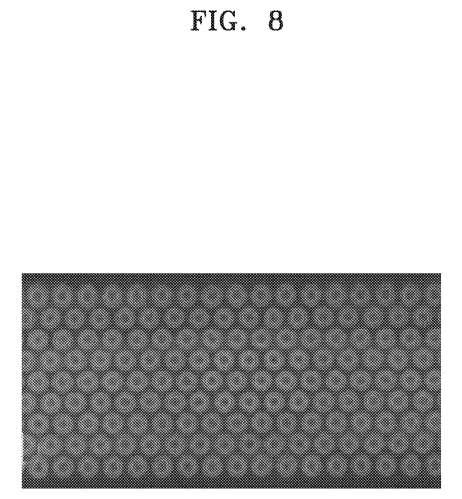

In a case where the de-layering process is performed by emitting light of a deep UV wavelength band onto the wafer WT, a per-material selectivity of the semiconductor device may be relatively uniform, and the non-uniformity and/or surface roughness Rₐ of the surface of the sample SP after the wafer WT is processed may be relatively low. Therefore, the reliability of a process of testing the sample SP may be relatively high. An operation of representing a surface after the wafer WT is processed will be described below in more detail with reference to FIG. 8.

For example, the wavelength converter 130 may include a harmonic generator, but the disclosure is not limited thereto.

The transfer unit 200 may transfer an optical signal, generated by the light source unit 100, to the stage 400. The transfer unit 200 may transfer the second laser beam LB2, generated by the light source unit 100 and having a converted wavelength band, to the stage 400. The transfer unit 200 may include a second mirror M2, a third mirror M3, a beam expander 210, a fourth mirror M4, a power meter 220, and an objective lens 230. The second mirror M2 and the third mirror M3 may transfer the second laser beam LB2, generated and emitted by the light source unit 100, to the beam expander 210.

The beam expander 210 may adjust a diameter of the second laser beam LB2. In one or more embodiments, the beam expander 210 may increase the diameter of the second laser beam LB2. In another embodiment, the beam expander 210 may decrease the diameter of the second laser beam LB2. The beam expander 210 may adjust the diameter of the second laser beam LB2 to adjust a diameter of a laser beam irradiated onto the wafer WT.

An optical signal emitted from the beam expander 210 may be incident on the power meter 220 via the fourth mirror M4. The fourth mirror M4 may control a path of the second laser beam LB2 such that the second laser beam LB2 emitted from the beam expander 210 is incident on the power meter 220.

The power meter 220 may measure an output of a laser beam. Whether an output of an optical signal is within a predetermined output range may be determined based on an output of an optical signal measured by the power meter 220. The output range may be an appropriate range for processing the wafer WT to form a sample. In one or more embodiments, when an output measured by the power meter 220 is outside the range, an output of a beam may be adjusted by adjusting the light source 110 of the light source unit 100. In one or more embodiments, the power meter 220 may be omitted.

The second laser beam LB2 emitted from the power meter 220 may be incident on the objective lens 230. The objective lens 230 may focus and collect the second laser beam LB2 incident thereon onto the wafer WT. The second laser beam LB2 may be emitted onto a predetermined region of the wafer WT by the objective lens 230.

For example, the second laser beam LB2 may have a spot size of a diameter of about 1 μm to about 150 μm, on the wafer WT. For example, the second laser beam LB2 may have a spot size of a diameter of about 1 μm to about 20 μm, on the wafer WT.

For example, the second laser beam LB2 may be incident on the wafer WT such that a de-layering milling angle is about 0 degrees to about 90 degrees. For example, the second laser beam LB2 may be incident on the wafer WT such that the de-layering milling angle is about 0 degrees to about 2 degrees.

For example, the second laser beam LB2 may be incident on the wafer WT such that a laser scanning speed is about 10 mm/s to about 3,000 mm/s. For example, the second laser beam LB2 may be incident on the wafer WT such that the laser scanning speed is about 50 mm/s to about 2,000 mm/s.

The scan unit 300 may photograph the wafer WT, and then, may provide data to a controller such that the wafer WT and the transfer unit 200 are aligned. The scan unit 300 may include a vision camera and may photograph the wafer WT to provide the data to the controller such that the wafer WT and the transfer unit 200 are aligned. For example, the scan unit 300 may transfer a position of the align key AK of the wafer WT to the controller. The controller may control a movement of the stage 400 to allow the wafer WT and the second laser beam LB2 to be aligned, based on the data transferred from the scan unit 300.

For example, the scan unit 300 may include an image sensor (for example, a complementary metal oxide semiconductor (CMOS) and/or a charge-coupled device (CCD)), an optical lens, and/or an illumination system. The image sensor may photograph the align key AK on the wafer WR, and the align key AK photographed by the image sensor may be analyzed by various algorithms such as a pattern recognition algorithm of the controller. Based on an analysis result, a relative position and/or rotation angle of the second laser beam LB2 on the wafer WT may be calculated, and based thereon, the wafer WT may move, and thus, the wafer WT and the second laser beam LB2 may be aligned.

For example, the scan unit 300 may generate and emit light of an infrared ray wavelength. For example, the scan unit 300 may have a field of view (FOV) of about 10 μm or less. For example, the scan unit 300 may have a pixel size of about 0.5 μm to about 3 μm. For example, the scan unit 300 may have a resolution of about 1 K to about 8 K. However, the disclosure is not limited thereto, and the scan unit 3 of various specs may be used for aligning the wafer WT and the second laser beam LB2.

The controller may be implemented with hardware, firmware, software, or an arbitrary combination thereof. For example, the controller may be a computing device such as a workstation computer, a desktop computer, a lap-top computer, or a tablet computer. For example, the controller may include a memory device such as read only memory (ROM) or random access memory (RAM) and a processor configured to perform a predetermined operation and algorithm, and for example, may include a microprocessor, a central processing unit (CPU), and a graphics processing unit (GPU). Moreover, the controller may include a receiver for receiving an electrical signal and a transmitter for transmitting an electrical signal.

The stage 400 may be a device which fixes and supports the wafer WT which is a process target, and the wafer WT may be disposed on the stage 400. The stage 400 may move the disposed stage 400 in a first horizontal direction (an X direction), a second horizontal direction (a Y direction), and/or a vertical direction (a Z direction). Also, the stage 400 may rotate on an X-Y plane with respect to a Z axis, or may rotate a Y-Z plane or an X-Z plane with respect to one axis (for example, a first horizontal axis (an X axis) and/or a second horizontal axis (a Y axis)) of the X-Y plane.

Herein, a direction parallel to a main surface of the stage 400 may be defined as a horizontal direction (an X direction and/or a Y direction), and a direction perpendicular to the horizontal direction (the X direction and/or the Y direction) may be defined as a vertical direction (a Z direction).

The stage 400 may further include a stage driver. The stage driver may move the stage 400 in the first horizontal direction (the X direction), the second horizontal direction (the Y direction), and/or the vertical direction (the Z direction). Also, the stage driver may rotate the stage 400. The stage driver may move the stage 400 to allow the wafer WT to be aligned with the second laser beam LB2. An operation of the stage driver may be controlled by the controller.

The sample SP may be formed by removing at least a portion of the wafer WT. For example, the sample SP may be in a state where a de-layering process has been performed on the wafer WT. For example, the sample SP may be in a state where a de-layering process has been performed on the wafer WT by a laser beam. Although described below in detail, analysis may be performed on the sample SP, and thus, a test may be more easily performed on a pattern of a semiconductor device.

For example, the sample SP may be formed by de-layering a layer of about 50 μm to about 200 μm of the wafer WT in the vertical direction (the Z direction). For example, the sample SP may be formed by de-layering a layer of about 80 μm to about 120 μm of the wafer WT in the vertical direction (the Z direction).

For example, the sample SP may be formed by de-layering a region of about 10 μm × about 10 μm to a region of about 3,000 μm × about 3,000 μm in the horizontal direction (the X direction and/or the Y direction). For example, the sample SP may be formed by de- layering a region of about 30 μm × about 30 μm to a region of about 1,000 μm × about 1,000 μm in the horizontal direction (the X direction and/or the Y direction).

Referring again to FIG. 4, in operation S200 of performing a de-layering process, a passivation layer may be first formed on the wafer WT in operation S220. For example, an oxide layer, a nitride layer, an organic insulation layer, an inorganic insulation layer, a metal layer, a carbon layer, and/or a silicon layer may be formed on the wafer WT. However, the disclosure is not limited thereto, and a passivation layer of various materials may be formed.

In one or more embodiments, the passivation layer may be formed on the wafer WT by a deposition process. For example, the passivation layer may be formed on the wafer WT by an atomic layer deposition (ALD) process, a physical vapor deposition (PVD) process, and/or a chemical vapor deposition (CVD) process.

At least a portion of each of the passivation layer and the wafer WT may be removed by emitting a laser beam onto a predetermined region of each of the passivation layer and the wafer WT in operation S240. Operation S240 may be performed by the sample manufacturing apparatus 10 described above. As described above, the sample manufacturing apparatus 10 may emit a laser beam onto a predetermined region of the wafer WT to perform a de-layering process. The wafer WT may include a hole through operation S240.

A residual passivation layer on the wafer WT may be removed in operation S260. For example, operation S260 may be performed by a mechanical chemical polishing process, but embodiments are not limited thereto.

The method and apparatus 10 of manufacturing the sample according to one or more embodiments may emit a laser beam onto the wafer WT to perform the de-layering process, thereby providing the method and apparatus 10 of manufacturing the sample, which have enhanced process reliability and an enhanced process speed.

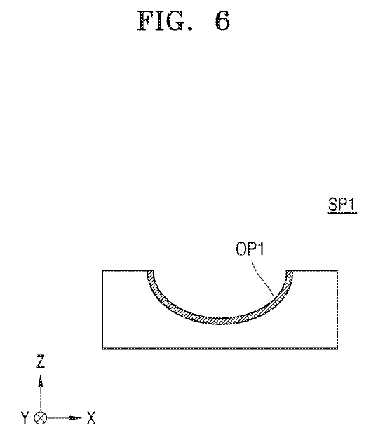

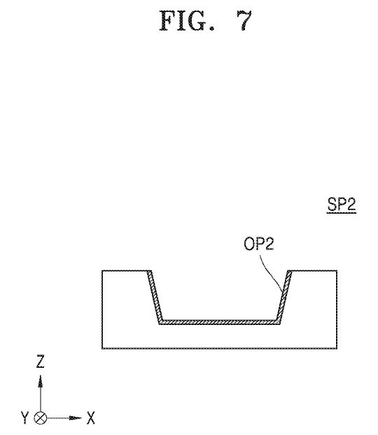

FIGS. 6 and 7 are cross-sectional views illustrating a shape of a sample according to one or more embodiments. FIGS. 6 and 7 may be described with reference to FIGS. 1 to 5.

Referring to FIG. 6, a first sample SP1 may include a first opening OP1 which is formed in an upper surface of a wafer WT. The first opening OP1 may have a crater shaped cross-section. The first opening OP1 may have a shape which is recessed by a predetermined depth from an upper surface of the first sample SP1 and may have a bowl-shaped cross-section with a horizontal width that downwardly increases and then decreases . In a case where the sample SP is manufactured to include the first opening OP1, a pattern of various vertical levels of a semiconductor device may be more easily tested.

Referring to FIG. 7, a second sample SP2 may include a second opening OP2 which is formed in an upper surface of the second sample SP2. The second opening OP2 may have a shape which is recessed by a predetermined depth from the upper surface of the second sample SP2 and may have a tapered shape with a horizontal width that decreases toward a lower surface of the second sample SP2. In a case where a sample is manufactured to include the second opening OP2, a pattern of a predetermined vertical level of a semiconductor device may be easily tested.

FIG. 8 is a scanning electron microscope (SEM) image illustrating a sample manufactured by a method of manufacturing a sample, according to one or more embodiments. FIG. 8 may be described with reference to FIGS. 1-7.

Referring to FIG. 8, the sample manufacturing apparatus 10 according to one or more embodiments may emit a laser beam onto a wafer WT to form a sample. As described above, in a case where a predetermined wavelength (deep UV) and a predetermined pulse width (a femtosecond laser beam) are used for forming the sample SP, a sample having a surface roughness Ra of about 50 nm or less may be formed. Accordingly, a pattern test device may test the sample SP with relatively high reliability. As illustrated in FIG. 8, in the sample SP manufactured by a method of manufacturing a sample according to one or more embodiments, it may be confirmed that a surface roughness and a uniformity of a pattern are good.

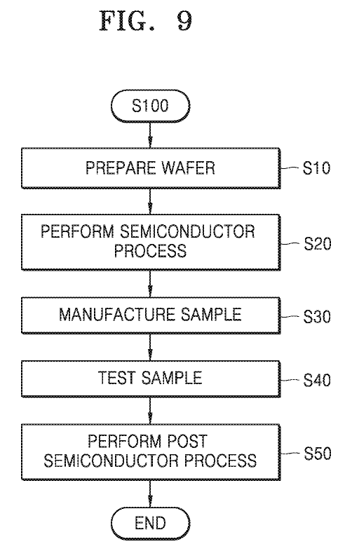

FIG. 9 is a flowchart illustrating a method of performing a semiconductor device, according to one or more embodiments. FIG. 9 may be described with reference to FIGS. 1 to 7.

Referring to FIG. 9, a wafer WT may be first prepared in operation S10. The wafer WT may include, for example, a bare wafer where one or more semiconductor processes have been performed, or a semiconductor process is not performed.

A semiconductor process may be performed on the wafer WT in operation S20. An oxidation process, a photo process, a deposition process, an etching process, an ion process, and/or a cleaning process may be performed on the wafer WT. As the semiconductor process is performed on the wafer WT, a pattern may be formed in the wafer WT.

An operation of manufacturing the sample SP may be performed in operation S30. The operation of manufacturing the sample SP may be performed by emitting a laser beam on the wafer WT to remove at least a portion of the wafer WT. The operation of manufacturing the sample SP may include operation S100 of preparing the wafer WT of FIG. 1 and operation S200 of perform de-layering by emitting a laser beam onto the wafer WT. Operation S200 of performing de-layering on the wafer WT may include operation S220 of forming a passivation layer on the wafer WT of FIG. 4, operation S240 of removing at least a portion of each of the wafer WT and the passivation layer, and operation S260 of removing a residual passivation layer.

The sample SP may be tested in operation S40. The sample SP may be tested by a test device. The test device may include various devices such as a wafer analysis device, a wafer measurement device, and/or a wafer test device. For example, the test device may include an X-ray diffraction (XRD) device, an X-ray fluorescence (XRF), a bright field (BF), a scanning electron microscope (SEM), a transmission electron microscope (TEM), an electron beam (E-Beam) test device, and/or an optical critical dimension (OCD) measurement device, but is not limited thereto.

A subsequent semiconductor process may be performed on the wafer WT in operation S50. A post semiconductor process on the wafer WT may include various processes. For example, the post semiconductor process may include an oxidation process, a photo process, a deposition process, an etching process, an ion process, and/or a cleaning process. Also, the post semiconductor process may include a singulation process of individualizing the wafer WT into semiconductor chips, a test process of testing the semiconductor chips, and a packaging process of packaging the semiconductor chips. A semiconductor device may be finished through the post semiconductor process on the wafer WT.

In one or more embodiments, the post semiconductor process on the wafer WT may include an operation of forming a capping layer in an opening of the sample SP. For example, the capping layer may include oxide, but embodiments are not limited thereto. As the capping layer is formed in the sample SP, the post semiconductor process on the wafer WT may be performed with relatively high reliability.

According one or more embodiments, there is provided a sample manufacturing apparatus including a light source unit including a light source configured to generate and emit a laser beam and a transfer unit configured to transfer the laser beam, emitted from the light source unit, to a wafer, wherein a sample is manufactured by emitting the laser beam onto an uncut wafer before being divided into individual chips.

The light source unit may further include a wavelength converter configured to convert a wavelength band of the laser beam generated and emitted by the light source.

The sample manufacturing apparatus may further include a scan unit configured to align the wafer and the laser beam.

The scan unit may be configured to photograph an align key of the wafer to align the wafer and the laser beam.

The transfer unit may be configured to emit a laser beam, having a spot size of a diameter of about 1 μm to about 20 μm, onto the wafer.

The light source unit may be configured to generate and emit a laser beam having a wavelength band of about 100 nm to about 1,100 nm.

The light source unit may be configured to generate and emit a laser beam having an inter-pulse time interval of about 50 kHz to about 1,000 kHz.

The light source unit may be configured to generate and emit a laser beam such that a penetration remain depth of the laser beam is disposed within a range from about 0.1 μm up to about 200 μm.

The transfer unit may further include a power meter configured to measure an output of the laser beam.

While embodiments have been shown and described with reference to the drawings and the specification, it will be understood by those of ordinary skill in the art that various modifications and other equivalent embodiments may be implemented from the disclosure. Accordingly, the spirit and scope of the disclosure may be defined based on the spirit and scope of the following claims.

While the disclosure has been particularly shown and described with reference to embodiments thereof, it will be understood that various changes in form and details may be made therein without departing from the spirit and scope of the following claims and their equivalents.

What is claimed is:

1. A method of manufacturing a sample, the method comprising:
preparing an uncut wafer; and
manufacturing a sample by emitting a laser beam onto the uncut wafer,
wherein the manufacturing of the sample comprises:
forming a passivation layer on the wafer;
removing at least a portion of each of the wafer and the passivation layer; and
removing a residual passivation layer.

2. The method of claim 1, wherein the manufacturing of the sample further comprises forming an opening recessed from an upper surface of the sample, the opening having a crater-shaped cross-section with a width in a horizontal direction increasing and then decreasing in a vertical direction.

3. The method of claim 1, wherein the manufacturing of the sample further comprises forming an opening recessed from an upper surface of the sample, the opening having a tapered shape with a width in a horizontal direction decreasing toward a lower surface of the sample.

4. The method of claim 1, wherein the removing of the at least a portion of each of the wafer and the passivation layer comprises emitting a femtosecond layer beam onto the wafer.

5. The method of claim 1, wherein the manufacturing of the sample comprises de-layering up to a region, corresponding to a chip region, of the wafer from a region, corresponding to a cell region, of the wafer.

6. The method of claim 1, wherein the manufacturing of the sample comprises forming an opening in an upper surface of the wafer such that a de-layering milling angle is 0 degrees to 2 degrees.

7. The method of claim 1, wherein the manufacturing of the sample comprises emitting a laser beam onto the wafer, a spot size of a diameter of the laser beam being 1 μm to 20 μm.

8. A method of manufacturing a sample, the method comprising:
preparing an uncut wafer; and
manufacturing a sample by emitting a laser beam onto the uncut wafer,
wherein the manufacturing of the sample comprises:
forming a passivation layer on the wafer;
removing at least a portion of each of the wafer and the passivation layer; and
removing a residual passivation layer, and
wherein the manufacturing of the sample further comprises aligning the wafer and a laser beam.

9. The method of claim 8, wherein the aligning of the wafer and the laser beam comprises photographing an align key of the wafer to move the wafer.

10. The method of claim 9, wherein the align key is in a scribe lane region of the wafer.

11. The method of claim 9, wherein the align key comprises a fiducial key.

12. The method of claim 8, wherein the manufacturing of the sample comprises emitting the laser beam onto the wafer such that a penetration remain depth of the laser beam is within a range from 0.1 μm up to 200 μm.

13. The method of claim 8, wherein the manufacturing of the sample comprises emitting a laser beam onto the wafer, a wavelength band of the laser beam being 100 nm to 1,100 nm.

14. The method of claim 8, wherein the manufacturing of the sample comprises emitting a laser beam onto the wafer, an inter-pulse time interval of the laser beam being 50 kHz to 1,000 kHz.

15. The method of claim 8, wherein the manufacturing of the sample comprises emitting a laser beam onto the wafer, an output of the laser beam being 0.5 W to 3 W.

16. The method of claim 8, wherein the manufacturing of the sample comprises de-layering a region in the wafer, a size of the region being 10 μm × 10 μm to 3,000 μm × about 3,000 μm in the horizontal direction.

17. A method of manufacturing a semiconductor device, the method comprising:
preparing a wafer;
performing a semiconductor process on the wafer;
manufacturing a sample based on the wafer on which the semiconductor process has been performed;
testing the manufactured sample; and
performing a post semiconductor process,
wherein the manufacturing of the sample comprises:
forming a passivation layer on the wafer;
removing at least a portion of each of the wafer and the passivation layer; and
removing a residual passivation layer, and
wherein the manufacturing of the sample is performed by emitting a laser beam onto an uncut wafer.

18. The method of claim 17, wherein the passivation layer comprises at least one of an oxide layer, a nitride layer, an organic insulation layer, an inorganic insulation layer, a metal layer, a carbon layer, and a silicon layer.

19. The method of claim 17, wherein the testing of the sample is performed by at least one of an X-ray diffraction (XRD) device, an X-ray fluorescence (XRF), a bright field (BF), a scanning electron microscope (SEM), an electron beam (E-Beam) test device, and an optical critical dimension (OCD) measurement device.

20. The method of claim 17, wherein the performing of the post semiconductor process comprises forming a capping layer in an opening of the sample.
